(19) United States
(12) Patent Application Publication
(10) Pub. No.: US 2010/0129940 A1
(43) Pub. Date: May 27, 2010

(54) VIBRATION MONITORING OF ELECTRONIC SUBSTRATE HANDLING SYSTEMS

(75) Inventor: Wilson T. Little, Frisco, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/276,553

(22) Filed: Nov. 24, 2008

(51) Int. Cl. H01L 21/66; G01H 11/06

(52) U.S. Cl. 438/14; 73/649; 257/E21.529

(57) ABSTRACT

An electronic device substrate handling system. The system comprises an electronic device fabrication tool and a mechanical handling structure. The fabrication tool is configured to hold at least one substrate on a mounting body of the tool. The mechanical handling structure is configured to actuate the substrate such that the substrate is transferred to or from the mounting body. The system further comprises a vibration monitor coupled to at least one of the mechanical handling structure, or, the tool. The vibration monitor is configured to measure vibrations of the mechanical handling structure, or, the tool, while said mechanical handling structure is actuating said substrate. The vibration monitor is also configured to convert the measured vibrations into a time-dependent electrical signal.

### TECHNICAL FIELD

The invention is directed, in general, to an electronic device substrate handling system, and more specifically, to detecting substrate handling errors by vibration monitoring, and, to the manufacture of electronic devices by fabrication processes that include such vibration monitoring.

### BACKGROUND

The manufacture of electronic devices often includes multiple transfers of a device substrate to and from and within various tools used in the device's fabrication. Transferring a device substrate to and from and within each tool, or between tools, is often facilitated by the use of a substrate handling system. Often the substrate handling system is automated or semi-automated, using computer-controlled robotic machines to perform the repetitive motions of introducing and removing the substrate from and within the tool, and coordinating the movement of multiple substrates between multiple tools.

Over a period of use, however, components of the substrate handling system or the tools can become misaligned or worn, causing errors in the handling of the substrate. Handling error, in turn, can damage or alter the substrate. For example, a handling system may accidentally cause a substrate to contact the wall of a tool while introducing or removing a substrate from the tool. The contact can cause material to become dislodged from the wall of the tool and fall onto the substrate. Or, contacting the wall can cause a scratch, chip, break or other physical damage to the substrate. In other cases, the handling error may result in the substrate not being positioned at the proper location in the tool, and therefore the substrate does not receive the intended processing performed by the tool.

Accordingly, what is needed is a method of manufacturing electronic devices by a process that includes the use of a substrate-handling system that minimizes damage or alteration to electronic device substrates by reducing handling errors, and thereby increase device yields.

### SUMMARY

One embodiment is an electronic device substrate handling system. The system comprises an electronic device fabrication tool and a mechanical handling structure. The fabrication tool is configured to hold at least one substrate on a mounting body of the tool. The mechanical handling structure is configured to actuate the substrate such that the substrate is transferred to or from the mounting body. The system further comprises a vibration monitor coupled to at least one of the mechanical handling structure, or, the tool. The vibration monitor is configured to measure vibrations of the mechanical handling structure, or, the tool, while the mechanical handling structure is actuating the substrate. The vibration monitor is also configured to convert the measured vibrations into a time-dependent electrical signal.

Another embodiment is a vibration monitoring module. the module comprises a vibration monitor and an analyzer module. The vibration monitor is coupleable to at least one of a mechanical handling structure or an electronic device fabrication tool. The vibration monitor is configured to measure and convert vibrations to electrical signals as described above. The analyzer module is coupleable to the vibration monitor. The analyzer module is configured to receive the electrical signal and detect a change in the electrical signal.

Still another embodiment is a method of manufacturing an electronic device. The method comprises performing a stage in a fabrication process flow. Performing the stage includes placing a substrate into a substrate handling system and actuating the substrate to or from a mounting body of a electronic device fabrication tool used in the stage. Actuating is performed using a mechanical handling structure of the substrate handling system. The method also comprises monitoring for a substrate-handling error while performing the actuating. Monitoring includes measuring vibrations from the substrate handling system using one or more vibration monitors coupled to the handling structure, or, the tool. Monitoring also includes converting the measured vibrations into time-dependent electrical signals. Monitor further includes determining whether or not the substrate-handling error has occurred by comparing the time-dependent electrical signals to a threshold value.

### DRAWINGS

FIG. 1 presents a perspective view of an example embodiment of an electronic device handling system of the disclosure;

FIG. 2 presents a perspective view of an example embodiment of vibration monitoring module of the disclosure; and

FIG. 3 presents a flow diagram of an example method of an embodiment of manufacturing an electronic device in accordance with the disclosure.

### DESCRIPTION

As part of the present disclosure, it was found that existing methods of monitoring of the performance of substrate handling systems can result in unacceptably high numbers of damaged substrates. For instance, the periodic inspection (e.g., particle counts or visual inspection) of device substrates, or, the testing of end-product electronic devices (e.g., integrated circuits, ICs, or, liquid crystal displays, LCDs) fabricated from the substrates, can reveal damage caused by substrate handling errors. However, hundreds of substrates may be processed before problems are detected, and, it may not be apparent where in the process the handling error occurred.

Sometimes, a vibration monitor can be attached directly to a substrate, and the vibrations that the substrate experiences while being fabricated can be recorded. The recording can then be examined for vibration anomalies to help identify where in the fabrication process a substrate handling error occurred. In some cases, however, it may not be desirable, or possible, to attach the vibration monitor to a substrate that is actually used in the fabrication of the electronic device.

For example, a substrate with a monitor attached to it does not have the same mass or shape as an actual device substrate (e.g., a substrate from which end products are actually made). The attached vibration monitor may change the mass and geometric shape of the substrate sufficiently to alter the ability of a substrate handler to move the monitor-attached substrate as compared to a device substrate. In some cases, therefore, the test substrate does not provide an accurate measure of substrate handling errors that actually occur for device substrates.

As another example, certain steps in the fabrication process may cause material from the vibration sensor to become deposited onto the substrate and thereby contaminate the substrate. These contaminants may alter the function of end-product electronic devices. To avoid such detrimental effects, the vibration monitor can be attached to a test substrate instead of an actual device substrate. However, as noted above, the presence of the vibration monitor may affect the movement of the substrate through the handler and therefore not provide accurate indications of handling errors.

As a third example, it may not be possible to expose the vibration monitor to all of the processes that a substrate is exposed to during a device's fabrication. For example, a vibration monitor may be damaged if it is exposed to dry or wet etching processes or to high-temperature thermal processes. Therefore it may not be possible to monitor potential handling errors for certain steps in the fabrication process.

As part of the present disclosure, it was discovered that vibration monitoring of the substrate handler itself, or, of a tool in the fabrication process, can be used to identify substrate handling errors. One might expect that placing a vibration monitor in locations that are remote from the substrate would detrimentally dampen the vibrations that the substrate experiences and that correspond to handling errors. It was surprising that indirect monitoring can provide useful information about substrate handling errors, given that there can be multiple vibrations occurring in the wafer handler or tool which are unrelated to errors in handling. It was unexpected that vibrations reflecting substrate handling errors can be effectively detected above background noise of other vibrations produced by the substrate handler or tool.

Moreover, there are advantages associated with vibration monitoring of the substrate handler or tool as compared to the direct vibration monitoring of a substrate. The vibrations of the substrate handler can be monitored at any step in the fabrication process, because the vibration monitor is not necessarily subjected to the processing environment of the substrate. Additionally, because the monitoring is indirect, monitoring for handling errors can be done for individual device substrates, and in some cases each and every device substrate.

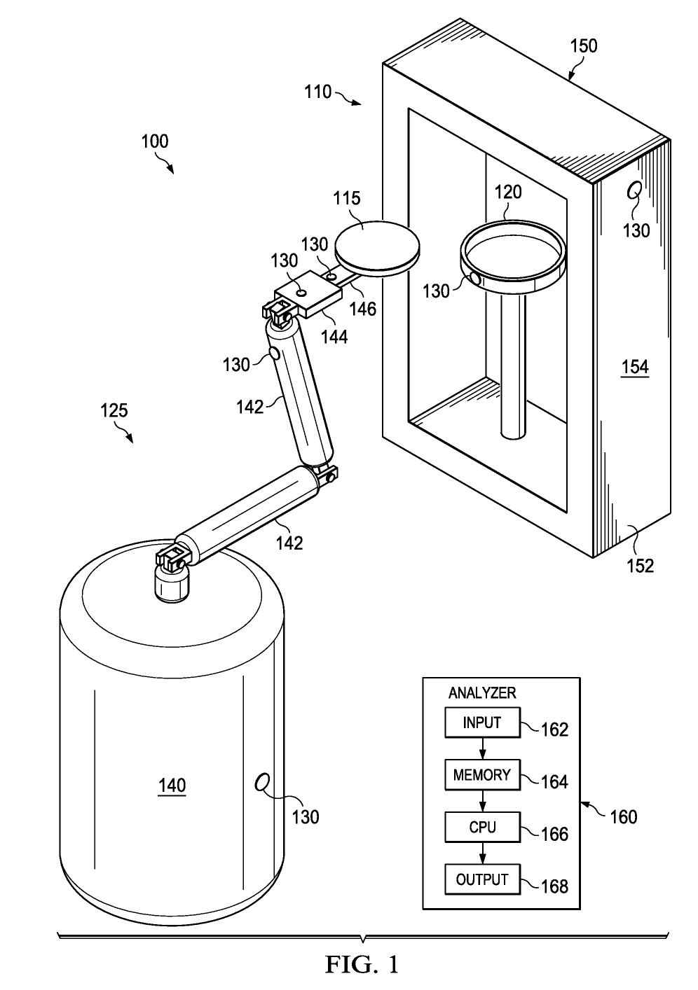

One aspect of the disclosure is an electronic device substrate handling system. FIG. 1 presents a perspective view of an example embodiment of a substrate handling system 100 of the disclosure.

The system 100 comprises an electronic device fabrication tool 110 configured to hold at least one substrate 115 on a mounting body 120 of the tool 110. The system 100 also comprises a mechanical handling structure 125 configured to actuate the substrate 115 such that the substrate 115 is transferred to or from the mounting body 120 of the tool 110. The system 100 further comprises a vibration monitor 130 coupled to at least one of the mechanical handling structure 125, or, the tool 110. The vibration monitor 130 is configured to measure vibrations of the mechanical handling structure 125, or, the tool 110 while the mechanical handling structure 125 is actuating the substrate 115. The vibration monitor 130 is also configured to convert the measured vibrations into a time-dependent electrical signal.

The tool 110 can be any structure that is configured to hold a substrate as part of the fabrication of an electronic device. Non-limiting examples of tools 110 include semiconductor wafer holding cartridges, such as a front opening unified pod (FOUP), plasma or wet etching tools, chemical mechanical polishers (CMP), photolithography processors, thermal diffusion, ashing ovens, or, other conventional tools familiar to those skilled in the art. The mounting body 120 can be any conventional location in the tool where substrates are normally held for some period during a fabrication process. For example, the mounting body 120 can be an orienteering structure of the FOUP, a platen in the CMP, or a pad or pedestal in an etching tool, a photolithography processor tool or an ashing tool. Transfers of the substrate 115 to or from the mounting body 120 can include inserting or removing the substrate 115 from the tool 110, as well as moving the substrate 115 within the tool 110 (e.g., from one mounting body 120 to a different mounting body 120 of the tool 110).

The mechanical handling structure 125, which is configured to actuate the substrate 115, can include or be any machine component part involved in the handling of a substrate. For example, the mechanical handling structure 125 can be or include one or more of a motor housing 140, arm 142, wrist 144, blade 146, or other component parts familiar to those skilled in the art. In preferred embodiments, the movement of the mechanical handling structure 125 is under robotic control. One skilled in the art would be familiar with other types of machine components (e.g., conveyer belts, stackers etc. . . . ) that the mechanical handling structure 125 could have to facilitate moving the substrate 115 to or from the desired mounting location 120.

The vibration monitor 130 as can be any mechanical or electronic apparatus that can measure mechanical vibrations, including sounds produced by mechanical vibrations, and that can convert these into electrical signals in real-time. That is, the vibration monitor 130 can measure moment-to-moment changes in the vibrations over time and convert these into a time-dependent electrical signal. It is an important to have the ability to measure real-time vibrations as a substrate is being handled so that unexpected handling error can be rapidly detected and localized to a particular stage, and substrate, in the fabrication process. For the purposes of the present disclosure, real-time measurements includes measurements that have a lag time (e.g., one to several seconds) between when a vibration occurs and when the corresponding electrical signal is formed and processed into useful information. The electrical signal can be, e.g., a current or voltage that is proportional to the amplitude of the vibration.

In some cases, the vibration monitor 130 includes or is an accelerometer sensor. One skilled in the art would be familiar with various type of accelerometers that can be used to measure mechanical vibrations, including piezoelectric, solid-state or strain-gage types of accelerometer mechanisms. A vibration monitor 130 having an accelerometer sensor has the advantage of being able to operate in a tool 110 with substantially no atmosphere. E.g., a plasma etch tool or chemical vapor deposition tool may operate at a chamber pressure of about 10⁻³ atmospheres, and a physical vapor deposition tool or ion implantation tool may operate at chamber pressure of about 10⁻6 atmospheres.

In other cases, the vibration monitor 130 includes or is an acoustic sensor. Acoustic sensors may be limited for uses in environments having an atmosphere (e.g., about 1 atmosphere of air or other gases), because sound waves are not transmitted efficiently at low atmospheric pressure. However, in some cases, acoustic sensors can provide a more accurate detection of handling errors than an accelerometer sensor. For example, an acoustic sensor can potentially provide a broad range of acoustic frequencies during substrate handling. Because there is a broad range of acoustic frequency responses, it can be easier to distinguish vibrations caused by handling errors from normal vibrations that are unrelated to handling errors, as compared to using an accelerometer sensor. For example, if a substrate, due to a handling error contacts a chamber wall of a tool, a very different acoustic frequency may be emitted as compared to cases where a substrate does not contact the chamber wall. Moreover, in some cases there may be transient harmonic frequencies emitted about the frequency of the sound emitted when there is a handling error. In some cases, for example, the presence or absence, or the amplitude, of the transient harmonic frequencies can be advantageously used to better determine the location and type of handling error that has occurred.

The vibration monitor 130 can be directly coupled to a component part of the mechanical handling structure 125, or, the tool 110. As further illustrated in FIG. 1 there can be a plurality of monitors 130 attached to different components of the handling structure 125 or the tool 110. In some cases, a second vibration monitor 130 is coupled to the other of the handling structure 125 or tool 110. For instance, the vibration monitor 130 can be attached to one or more of the motor housing 140, arm 142, wrist 144, blade 146 parts of the handling structure 125. Or, the vibration monitor 130 can be attached to one or more of a chamber 150, or, to the mounting body 120 in the chamber 150 of the tool 110. The use of multiple vibration monitors 130 can help to better determine the location and time when a handling error occurs.

Consider the case, e.g., when the vibration monitor 130 includes an acoustic sensor, and the chamber 150 is maintained at a low atmospheric pressure (e.g., less than about 0.1 atmosphere) during the time the wafer is transferred into or out of the tool 110. In such cases, can be advantageous for an acoustic vibration monitor 130 to be attached to an outside surface 152 of a chamber wall 154. However, in situations where the chamber 150 has a substantial atmosphere (e.g., greater than about 0.1 atmosphere), the acoustic vibration monitor 130 can be attached to the mounting body 120 of other location in the chamber 150 that is in close proximity to where the substrate 115 is actuated to or from.

In some cases, it can be advantageous to attach the vibration monitor 130 to a component part that is close to the substrate 115, because vibrations due to handling errors can be more prominent as compared to other vibrations occurring in the normal course of substrate handling, and, that are unrelated to handling errors. E.g., it can be more desirable to attach the vibration monitor 130 to the blade 146 of the mechanical handling structure 125 as compared to the arm 142 or the wrist 144 because the substrate 115 directly contacts the blade 146 during its handling. Similarly, it can be more desirable to attach the vibration monitor 130 to the mounting body 120 as compared to the chamber wall 154 because the substrate 115 rests directly on the mounting body 120.

In some embodiments, the vibration monitor 130 is configured to measure the vibrations from individual ones of each substrate 115 that is actuated by the mechanical handling structure. For instance, in some preferred embodiments, the substrate 115 is a device substrate, such as a semiconductor wafer, upon which electronic devices, such as an integrated circuit (IC) devices, are formed. Or, the substrate 115 is one or more of the thin film substrates (e.g., glass substrates), upon which electro-optical amplitude modulator devices, such as LCDs, are formed. Even more preferably, each and every device substrate 115 that is passed through the system 100 is monitored for vibrations to identify potential handling errors. This is in contrast to embodiments where a test substrate 115 is only periodically run through the system 100 to check for handling errors.

In some embodiments, the vibration monitor 130 is implanted within, and in some cases, fully enclosed within the mechanical handling structure 125 or the tool 110. Sometimes it is more preferable for the implanted vibration monitor 130 to include an accelerometer sensor instead of an acoustic sensor because the sensitivity of the latter type of sensor may be substantially decreased when it is implanted within a structure 125.

Implanting the monitor 130 can be advantageous in situations where the vibration monitor 130 would otherwise be exposed to harsh environments (e.g., radio-frequency plasma fields or etching chemicals) that otherwise would damage the monitor 130. For example, the monitor 130 can be implanted inside of one of the component parts of the mechanical handling structure 125 or the tool 110 such that it is not exposed to the harsh environment.

Implanting the monitor 130 can also be advantageous in situations where the vibration monitor 130 would otherwise obstruct the normal movement of the mechanical handling structure 125 or the tool 110 during its operation. For example, it can be desirable to implant the monitor 130 inside of the arm 142, the wrist 144, or the blade 146, if a monitor 130 attached to the outside surface of these structures could physically obstruct the normal range of motion of these components during a wafer handling operation.

As further illustrated in FIG. 1, some embodiments of the system 100 can further include an analyzer 160 (shown as a block diagram) coupled to the vibration monitor 130. The analyzer 160 is configured to receive the time-dependent electrical signals generated by the monitor 130 in response to vibrations. Coupling can be achieved by a wired or a wireless connection between the analyzer 160 and the monitor 130. The analyzer 160 is also configured to process the time-dependent electrical signals and detect changes in the signal that indicate a handling error.

One skilled in the art would be familiar with parts that the analyzer 160 could have to facilitate the analyzer's function. For example, the analyzer 160 can include an input module 162 configured to receive the electrical signals and memory module 164 configured to store electrical signals, a central processing unit (CPU) 166 configured to perform operations on the stored or incoming signals and an output module 168.

In some embodiments, the analyzer 160 is also configured to interdict in a stage in device fabrication if the change in the electrical signal corresponding to a handling error exceeds a threshold value. Interdiction can range, for example, from immediately stopping a fabrication step to sending a warning alert to a system operator. For instance, the output module 168 can be configured to send signals to other components of the system 100 (e.g., the tool 110 or mechanical handling structure 125) or to a system operator (e.g., a human or computer controlling the system's operation).

The analyzer 160 can be configured to process the time dependent electrical signal to facilitate the detection of substrate handling errors. In some preferred embodiments, as part of interpreting the electrical signal, the analyzer 160 is configured to transform the time-dependent electrical signal into a frequency-dependent signal (e.g., vibration spectra). For instance, the CPU 166 can be configured to perform Fourier transform operations on the incoming or stored electrical signal. Transforming the time-dependent electrical signal into a frequency-domain spectrum can make it easier to distinguish normal vibrations from vibrations due to handling errors.

In some embodiments, the analyzer 160 is configured to calculate a time-average of the amplitude of the electrical signal and compares the time average to a threshold value. E.g., if the magnitude of the vibrations over a period of substrate handling, as measured by the time-averaged amplitude of the electrical signal, exceeds the threshold value, then the analyzer may send an interdiction signal to shutdown the tool 110 or mechanical handling structure 125, or, to alert the operator. The threshold value can be determined experimentally, e.g., by measuring the average and standard deviation (SD) of the vibration obtained under control conditions when handling errors are known not to occur. The threshold value can be set to a multiple of the standard deviation (e.g., 3×SD) measured under these control conditions.

Alternatively or additionally, in cases where, e.g., the average vibration does not substantially change when a handling error occurs, the analyzer can be configured to calculate the amplitude of the vibration (e.g., the minimum and maximum electrical signal over a predefine period of substrate handling). Or, the analyzer can be configured to calculate the rate of change of the vibration. One skilled in the art would be familiar with other ways to detect anomalous vibrations associated with handling errors. E.g., in some embodiments, the CPU 166 can be configured to operate a tool interdiction monitoring system software program, (e.g., TIMS, Texas, Instruments, Dallas, Tex.) which is configured to identify anomalous changes in the electrical signal.

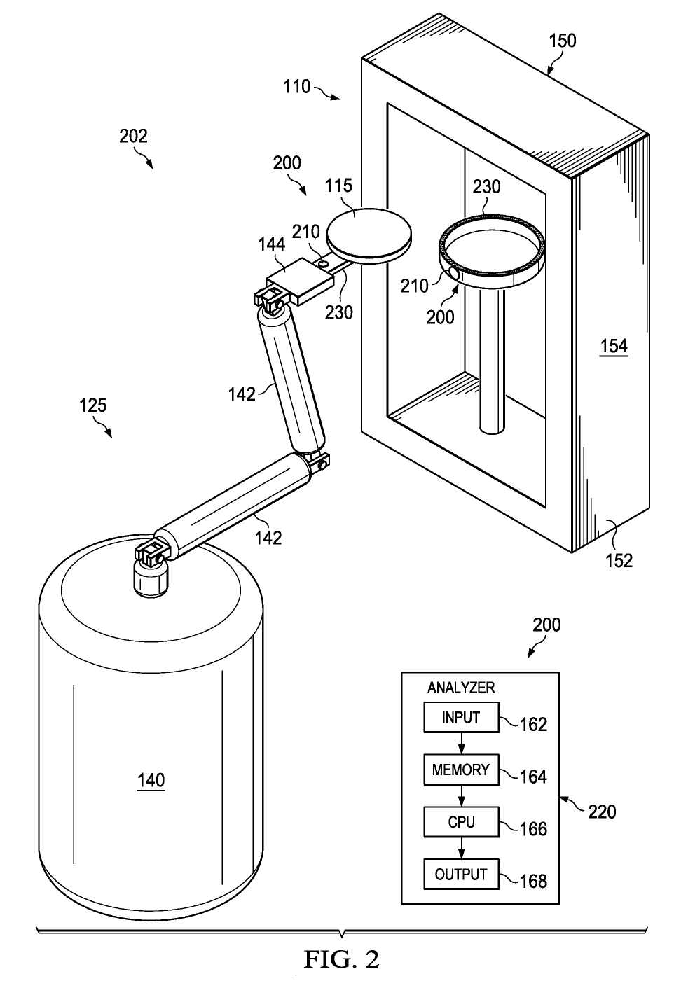

Another aspect of the invention is a vibration monitoring module. In some cases, the vibration monitoring module is retrofit kit that can be added to, or replace, components of an existing substrate handling system. FIG. 2 shows an example vibration monitoring module 200 of the disclosure attached to a substrate handling system 202 that is analogous to the system 100 described in the context of FIG. 1, except that the system 202, until the addition of the module 200, did not have the capability to monitor substrate handling errors in the manner disclosed herein. Similar reference numbers are used to designate component parts of the system 202 that are analogous to system 100 depicted in FIG. 1.

The vibration monitoring module 200 comprises a vibration monitor 210 and an analyzer module 220. The vibration monitor 210 and analyzer module 220 can comprise any of the embodiments discussed above in the context of FIG. 1.

The vibration monitor 210 is coupleable to at least one of a mechanical handling structure 125 or an electronic device fabrication tool 110. The vibration monitor 210 is configured to measure vibrations from the handling structure 125 or the tool 110 while the handling structure 125 is actuating a substrate 115 to or from the tool 110. The vibration monitor 210 is configured to convert these measured vibrations into a time-dependent electrical signal. The analyzer module 220 coupleable (e.g., through wired or wireless communication means) to the vibration monitor 210, and the analyzer module 220 is configured to receive the electrical signal and detect a change in the electrical signal.

In some embodiments, the analyzer module 220 includes a replacement module 230 of one of the components of the handling structure 125 or tool 110. The vibration monitor 210 can be included in the replacement module 230. For example, the vibration monitor 210 can be included within one or more replacement modules 230 configured to be a component part of the handling structure 125 or the tool 110. Including the vibration monitor 210 as part of a replacement module 230 has the advantage of minimizing or eliminating effects that the presence of the monitor 210 might have on the operation of the handling structure 125 or the tool 110. For instance, the replacement module 230 can have substantially the same weight, shape and composition as the original component part (e.g., a blade 146 or a mounting body 120, FIG. 1) except that the vibration monitor 210 is within the part 230. In other cases, however, the vibration monitor 210 can be a separate structure attached to the original component part of the system, similar to that shown for the monitors 130 depicted in FIG. 1.

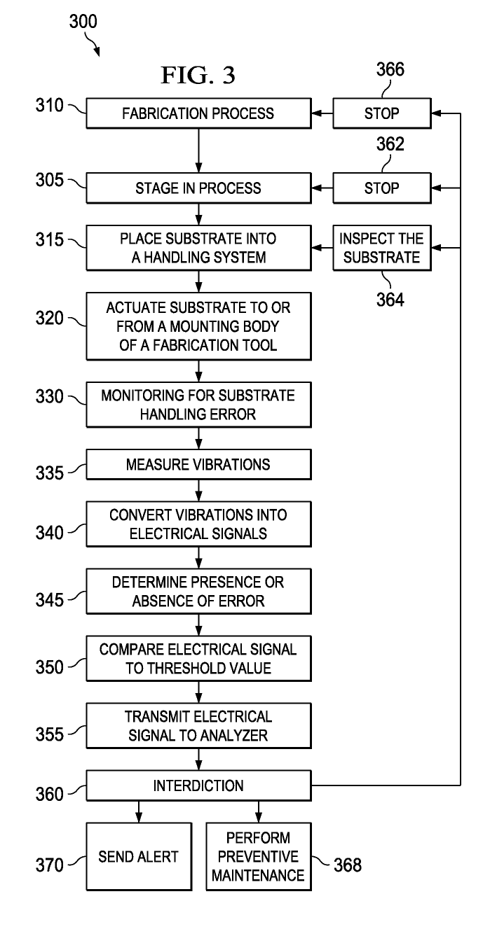

Another aspect of the invention is a method of manufacturing an electronic device that includes monitoring substrate handling errors. Any of the embodiments of electronic devices, substrates, substrate handling, fabrication tools and vibration monitoring, such as described above and in the context of FIGS. 1-2, can be used in the manufacture of the device and the monitoring of handling errors. FIG. 3 presents a flow diagram of an example method 300 of an embodiment of manufacturing an electronic device in accordance with the disclosure.

The method 300 includes performing a stage (step 305) in a fabrication process flow (step 310). The fabrication process flow can be any conventional process used in the fabrication of an electronic device that includes a substrate, and the stage (step 305) can be at any stage in the flow 310 where a substrate handling error can occur.

The stage (step 305) in the fabrication process further includes a step 315 of placing a substrate into a substrate handling system, and a step 320 of actuating the substrate to or from a mounting body of an electronic device fabrication tool used in the step 310. The actuating step 320 is performed using a mechanical handling structure of the substrate handling system.

The method 300 further includes a step 330 of monitoring for a substrate-handling error while performing the actuating step 320. Monitoring (step 330) includes a step 335 of measuring vibrations from the substrate handling system using one or more vibration monitors coupled to the mechanical handling structure, or, the tool. Monitoring (step 330) also includes a step 340 of converting the vibrations into time-dependent electrical signals.

Monitoring (step 330) further includes a step 345 of determining whether or not a substrate-handling error has occurred by comparing, in step 350, the time-dependent electrical signals to a threshold value. In some cases, the step 345 of determining the presence or absence of a handling error, can includes transmitting, in step 355 the time-dependent electrical signal to an analyzer that is configured to compare the electrical signal to the threshold value.

Embodiments of the method 300 can further include interdicting (step 360) in the fabrication process flow 310 if the electrical signal exceeds the threshold value. As illustrated in FIG. 3, interdiction can occur at several different levels in the flow 310. For example, interdiction (step 360) can include a step 362 of stopping the stage (step 305) in the fabrication process (e.g., immediately or after finishing the stage 305), and, a step 364 of inspecting the substrate for damage. If the substrate is not damaged, it can be returned to the flow 310. If the substrate is damaged, it can be designated as a scrap substrate, and not further processes by the flow 310, or, returned to the beginning of the flow 310 for reprocessing.

In some cases, interdiction (step 360) includes stopping (step 366) the fabrication process flow 310 after performing the flow 310 on an entire lot of the substrates.

In other cases, interdiction (step 360) can include a step 368 performing a preventive maintenance procedure on the substrate handling system, or, on the tool. In still other instances, interdicting (step 360) can include a step 370 of sending an alert to an operator of the fabrication process flow 310.

One skilled in the art would understand that monitoring 330 and interdicting 360 and their sub-steps can be done at any number or all of the stages 305 in the flow 310 where a substrate handling error could occur. One skilled in the art would also be familiar with the details of the processing stages 305 that are performed in the flow 310 to produce the end-product device (e.g., an IC or LCD).

Those skilled in the art to which the invention relates will appreciate that other and further additions, deletions, substitutions and modifications may be made to the described example embodiments, without departing from the invention.

What is claimed is:

1. A electronic device substrate handling system, comprising:
an electronic device fabrication tool configured to hold at least one substrate on a mounting body of said tool;
a mechanical handling structure configured to actuate said substrate such that said substrate is transferred to or from said mounting body;
a vibration monitor coupled to at least one of said mechanical handling structure, or, said tool, wherein said vibration monitor is configured to:
measure vibrations of said mechanical handling structure, or, said tool, while said mechanical handling structure is actuating said substrate, and
convert said measured vibrations into a time-dependent electrical signal.

2. The system of claim 1, wherein said vibration monitor includes an accelerometer sensor.

3. The system of claim 1, wherein said vibration monitor includes an acoustic sensor.

4. The system of claim 1, wherein said vibration monitor is implanted within one of said mechanical handling structure, or, said tool.

5. The system of claim 1, wherein a second said vibration monitor is coupled to the other of said mechanical handling structure, or, said tool.

6. The system of claim 1, further including an analyzer coupled to said vibration monitor, wherein said analyzer is configured to receive said electrical signal.

7. The system of claim 1, wherein said substrate is a device substrate.

8. The system of claim 1, wherein said vibration monitor is configured to measure said vibrations from individual ones of each said substrate that is actuated by said mechanical handling structure.

9. The system of claim 1, wherein said vibration monitor is attached to one or more parts of said mechanical handling structure configured as an arm, wrist, blade or motor housing.

10. The system of claim 1, wherein said vibration monitor is attached to a one or more parts of said tool configured as a chamber wall or said mounting body.

11. The system of claim 1, wherein said substrate is a semiconductor wafer substrate.

12. The system of claim 1, wherein said substrate is an electro-optical amplitude modulator device substrate.

13. A vibration monitoring module, comprising:
a vibration monitor coupleable to at least one of a mechanical handling structure or an electronic device fabrication tool, wherein said vibration monitor is configured to measure vibrations from said handling structure or said fabrication tool while said handling structure is actuating a substrate to or from said tool, and to convert said measured vibrations into a time-dependent electrical signal; and
an analyzer module coupleable to said vibration monitor, wherein said analyzer module is configured to receive said electrical signal and detect a change in said electrical signal.

14. A method of manufacturing an electronic device, comprising:
performing a stage in a fabrication process flow, including:
placing a substrate into a substrate handling system, and
actuating said substrate to or from a mounting body of a electronic device fabrication tool used in said stage, said actuating performed using a mechanical handling structure of said substrate handling system; and
monitoring for a substrate-handling error while performing said actuating, including:
measuring vibrations from said substrate handling system using one or more vibration monitors coupled to said mechanical handling structure, or, said tool, and
converting said measured vibrations into time-dependent electrical signals, and
determining whether or not said substrate-handling error has occurred by comparing said time-dependent electrical signals to a threshold value.

15. The method of claim 14, wherein said determining further includes transmitting said time-dependent electrical signal to an analyzer configured to compare said electrical signal to said threshold value.

16. The method of claim 14, further including interdicting in said fabrication process flow if said electrical signal exceeds said threshold value.

17. The method of claim 16, wherein said interdicting includes stopping said stage and inspecting said substrate for damage.

18. The method of claim 16, wherein said interdicting includes stopping said fabrication process flow after performing said fabrication process flow on an entire lot of said substrates.

19. The method of claim 16, wherein said interdicting includes performing a preventive maintenance procedure on said substrate handling system, or, on said tool.

20. The method of claim 16, wherein said interdicting includes sending an alert to an operator of said fabrication process flow.
